(19) United States
(12) Patent Application Publication
(10) Pub. No.: US 2025/0267851 A1
(43) Pub. Date: Aug. 21, 2025

(54) SEMICONDUCTOR STRUCTURE AND METHOD FOR FORMING THE SAME

(71) Applicant: Winbond Electronics Corp., Taichung City (TW)

(72) Inventors: Noriaki IKEDA, Kaohsiung City (TW); Hsiang-Po LIU, Taichung City (TW); Shou-Chi TSAI, Kaohsiung City (TW)

(73) Assignee: Winbond Electronics Corp., Taichung City (TW)

(21) Appl. No.: 19/030,169

(22) Filed: Jan. 17, 2025

(30) Foreign Application Priority Data
Feb. 19, 2024 (TW) 113105790

(51) Int. Cl. H10B 12/00

(52) U.S. Cl. CPC H10B 12/34; H10B 12/053

(57) ABSTRACT

A semiconductor structure includes an active region over a semiconductor substrate, a gate structure embedded in the active region and including a gate dielectric layer and a gate electrode nested within the gate dielectric layer, and an insulating structure embedded in the active region and over the gate electrode. The insulating structure includes a dielectric liner layer and a dielectric fill layer nested within the dielectric liner layer. The dielectric liner layer has a first hydrogen concentration. The dielectric fill layer has a second hydrogen concentration. The second hydrogen concentration is lower than the first hydrogen concentration.

### CROSS REFERENCE TO RELATED APPLICATIONS

This application claims the benefit of Taiwan Patent Application No. 113105790 filed on Feb. 19, 2024, entitled “SEMICONDUCTOR STRUCTURE AND METHOD FOR FORMING THE SAME” which is hereby incorporated herein by reference.

### BACKGROUND

### Field of the Disclosure

The present disclosure relates in general to a semiconductor structure and a method for forming the same, and in particular, it relates to dynamic random access memory and a method for forming the same.

### Description of the Related Art

In order to increase the component density within Dynamic Random Access Memory (DRAM) devices and enhance their overall performance, current manufacturing techniques for DRAM devices are continually striving towards miniaturization of components through a reduction in their overall sizes. Therefore, improving the manufacturing methods of DRAM devices is a crucial challenge that must be addressed at present.

### SUMMARY

The semiconductor structure includes an active region over a semiconductor substrate, a gate structure embedded in the active region and including a gate dielectric layer and a gate electrode nested within the gate dielectric layer, and an insulating structure embedded in the active region and over the gate electrode. The insulating structure includes a dielectric liner layer and a dielectric fill layer nested within the dielectric liner layer. The dielectric liner layer has a first hydrogen concentration. The dielectric fill layer has a second hydrogen concentration. The second hydrogen concentration is lower than the first hydrogen concentration.

The method of forming a semiconductor structure includes forming a trench in an active region, forming a gate dielectric layer along the trench, forming a gate electrode on the gate dielectric layer to fill a lower portion of the trench, and depositing a dielectric liner layer over the gate electrode to partially fill an upper portion of the trench. The dielectric liner layer contains hydrogen and has a hydrogen concentration greater than 5%. The method further includes depositing a dielectric fill layer over the dielectric liner layer to fill the upper portion of the trench.

### BRIEF DESCRIPTION OF THE DRAWINGS

In accordance with some embodiments of the present disclosure, it may be further understood by reading the subsequent detailed description and examples with references made to the accompanying drawings, wherein:

FIG. 1 is a plan view illustrating a semiconductor structure, in accordance with some embodiments.

FIGS. 2-6 are cross-sectional views illustrating the formation of a semiconductor structure at various intermediate stages, in accordance with some embodiments.

### DETAILED DESCRIPTION

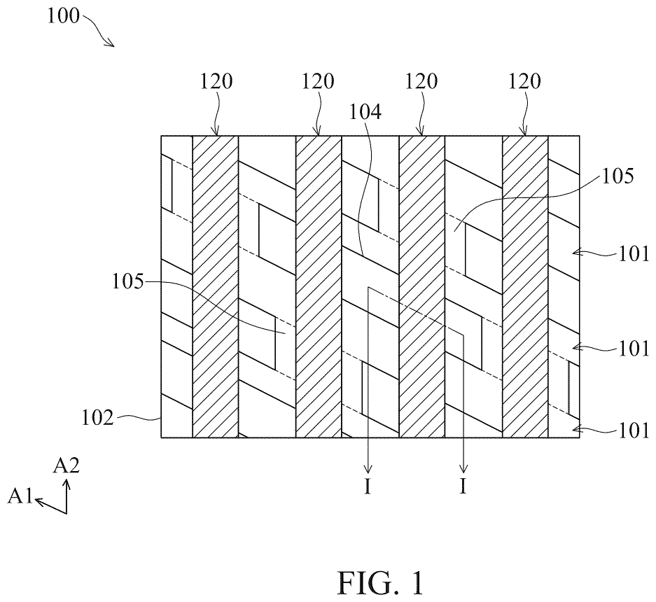

FIG. 1 is a plan view illustrating a semiconductor structure 100, in accordance with some embodiments of the present disclosure. The semiconductor structure 100 includes a semiconductor substrate 102. The semiconductor substrate 102 includes active regions 104, isolation regions 101, and chop regions 105. The semiconductor structure 100 is a dynamic random access memory (DRAM) device.

The active regions 104 are semiconductor blocks extending along a first direction A1, with each active region 104 being defined by two isolation regions 101 and two chop regions 105. Isolation structure (not shown) is disposed in the isolation regions 101 and the chop regions 105 of the semiconductor substrate 102, and surrounds and electrically isolates the active regions 104. The isolation structure may be made of dielectric materials.

The isolation regions 101 extend along the first direction A1 and are spaced apart from each other in a second direction A2, thereby dividing the semiconductor substrate 102 into multiple semiconductor strips (not shown). The first direction A1 is the channel extending direction, and the second direction A2 is the gate extending direction. The angle between the first direction A1 and the second direction A2 is acute, ranging from about 10 degrees to about 80 degrees. The chop regions 105 (indicated by dashed lines) are disposed corresponding to the semiconductor strips and chop the semiconductor strips into the active regions 104. In the second direction A2, adjacent chop regions 105 may be staggered or non-overlapping. For example, in the second direction A2, the chop regions 105 can be periodically arranged (e.g., overlapping) for every few semiconductor strips (e.g., 2 to 5).

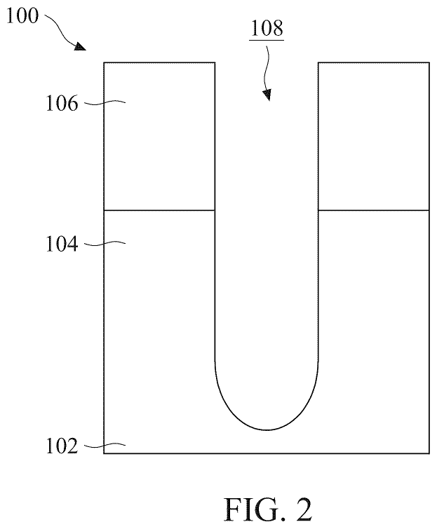

The semiconductor structure 100 also includes gate structures 120. The gate structures 120 are embedded in the semiconductor substrate 102. Each gate structure 120 extends along the second direction A2, alternately passing through the active region 104 and the isolation structure. Each active region 104 is penetrated by two gate structures 120. For clarity in the illustration, FIG. 1 only shows these components, while the remaining components of the semiconductor structure 100 can be seen in the cross-sectional views of FIGS. 2 to 6.

FIGS. 2 to 6 are cross-sectional views illustrating the formation of the semiconductor structure 100 at various intermediate stages in accordance with some embodiments of the present disclosure. FIGS. 2 to 6 are taken along cross-section I-I in FIG. 1.

The following describes the method for forming the semiconductor structure 100. Referring to FIG. 2, a semiconductor substrate 102 is provided. In some embodiments, the semiconductor substrate 102 may be an elemental semiconductor substrate, such as a silicon substrate or a germanium substrate; or a compound semiconductor substrate, such as a silicon carbide substrate or a gallium arsenide substrate. In some embodiments, the semiconductor substrate 102 may be a semiconductor-on-insulator (SOI) substrate.

Next, an isolation structure is formed in the semiconductor substrate 102 to define the active regions 104. In some embodiments, the isolation structure is made of dielectric material, such as silicon dioxide (SiO), silicon nitride (SiN), silicon oxynitride (SiON), and/or combinations thereof. The formation of the isolation structure may include using one or more etching processes to form trenches corresponding to the isolation regions 101 and chop regions 105 as shown in FIG. 1. Dielectric material for the isolation structure is then deposited using chemical vapor deposition (CVD) and/or atomic layer deposition (ALD). Subsequently, the dielectric material is planarized using such as etching-back and/or chemical mechanical polishing (CMP).

An ion implantation process is performed on the semiconductor structure 100 to form source/drain regions 106. The ion implantation process introduces dopants (e.g., n-type dopants such as phosphorus or p-type dopants such as boron) into the active regions 104.

A patterning process is performed on the semiconductor structure 100 to form trenches 108 for the gate structures 120 in the semiconductor substrate 102. The trenches 108 extend horizontally through the active regions 104 and the isolation structure (not shown). The trenches 108 extend vertically to a depth lower than the bottom surfaces of the source/drain regions 106. The patterning process may include forming a patterned mask layer (not shown) on the semiconductor substrate 102 using a photolithography process, and then transferring the opening patterns of the patterned mask layer to the semiconductor substrate 102 using an etching process, thereby forming the trenches 108.

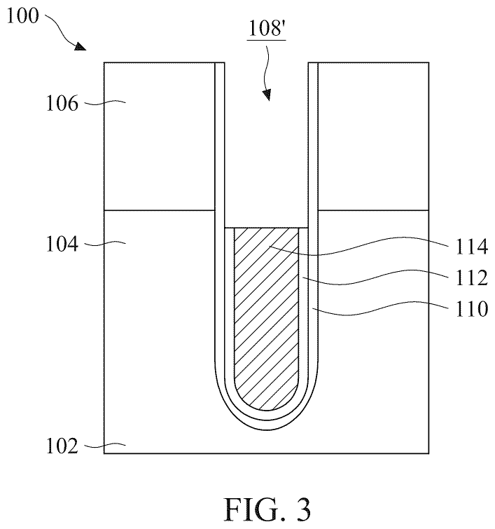

Referring to FIG. 3, a dielectric layer 110 is formed to partially fill the trench 108. The gate dielectric layer 110 lines the surface of the active regions 104 exposed from the trench 108. The gate dielectric layer 110 is made of silicon nitride and can be formed using in-situ steam generation (ISSG), chemical vapor deposition (CVD), and/or atomic layer deposition (ALD).

A first gate liner layer 112 and first work function layer 114 are sequentially formed over the gate dielectric layer 110 to fill the lower portion of the trench 108. The first work function layer 114 is nested within the first gate liner layer 112. In some embodiments, the first gate liner layer 112 is made of titanium nitride (TiN), tungsten nitride (WN), and/or tantalum nitride (TaN). In some embodiments, the first work function layer 114 is made of a metal material, such as tungsten (W), aluminum (Al), copper (Cu), cobalt (Co), ruthenium (Ru), and/or other metal materials. The first gate liner layer 112 and the first work function layer 114 can be deposited using physical vapor deposition (PVD), chemical vapor deposition (CVD), and/or atomic layer deposition (ALD).

After depositing the material for the first work function layer 114, an etching-back process is performed on the first gate liner layer 112 and the first work function layer 114 to expose the gate dielectric layer 110. The upper portion of the trench 108 are not fully filled and are denoted as a trench 108′. During the etching-back process, the gate dielectric layer 110 remains substantially unetched.

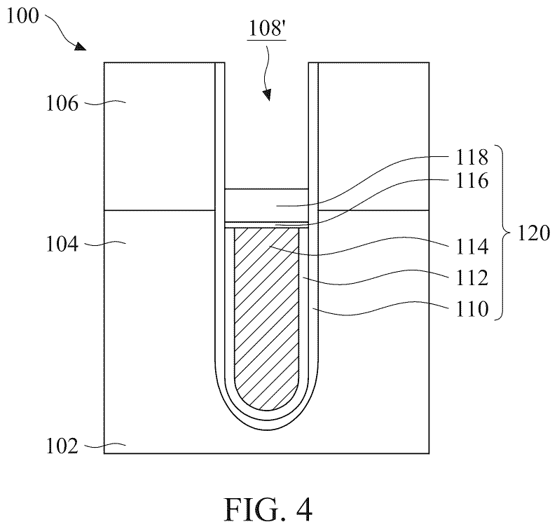

Referring to FIG. 4, a second gate liner layer 116 is formed over the first gate liner layer 112 and the first work function layer 114 to partially fill the trench 108′. The first gate liner layer 112 and the second gate liner layer 116 collectively surround the first work function layer 114 to prevent the material of the first work function layer 114 (e.g., tungsten) from diffusing into the gate dielectric layer 110. In some embodiments, the second gate liner layer 116 is made of titanium nitride (TiN), tungsten nitride (WN), and/or tantalum nitride (TaN). The second gate liner layer 116 may be deposited using chemical vapor deposition (CVD), physical vapor deposition (PVD), and/or atomic layer deposition (ALD), followed by an etching-back process. During the etching-back process, the gate dielectric layer 110 remains substantially unetched.

A second work function layer 118 is formed over the second gate liner layer 116 to partially fill the trench 108′. The first gate liner layer 112, the first work function layer 114, the second gate liner layer 116, and the second work function layer 118 together form the gate electrode, and the gate electrode and the gate dielectric layer 110 constitute the gate structure 120. The gate structure 120 may be configured as a word line of the resulting semiconductor memory device, such as a buried word line (BWL).

In some embodiments, the second work function layer 118 is made of polysilicon. The formation of the second work function layer 118 may include using a chemical vapor deposition (CVD) process to deposit the second work function layer 118 to overfill the trench 108′, followed by an etching-back process. During the etching-back process, the gate dielectric layer 110 remains substantially unetched. The bottom surfaces of the source/drain regions 106 may be located between the upper surface and the bottom surface of the second work function layer 118.

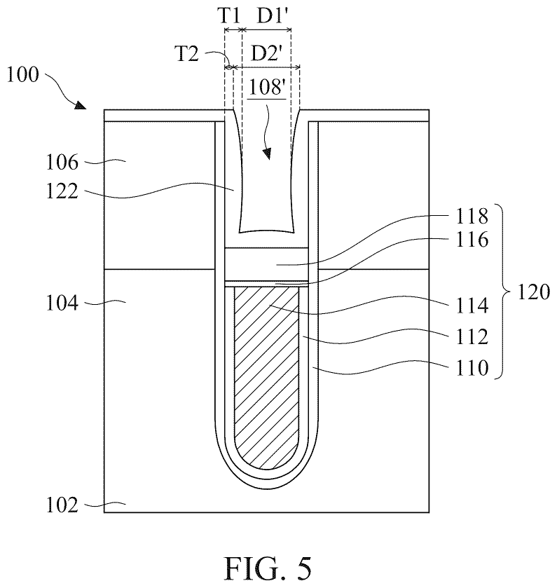

Referring to FIG. 5, a dielectric liner layer 122 is formed over the semiconductor structure 100 to partially fill the trench 108′. The dielectric liner layer 122 extends over the upper surfaces of the active regions 104 (or the source/drain regions 106), the surface of the gate dielectric layer 110 exposed by the trench 108′, and the upper surface of the second work function layer 118 exposed by the trench 108′. The dielectric liner layer 122 is made of dielectric materials, such as silicon nitride (SiN), silicon dioxide (SiO), silicon oxynitride (SiON), silicon oxycarbide (SiOC), silicon carbon oxynitride (SiOCN), silicon carbon nitride (SiCN), and/or combinations thereof.

The dielectric liner layer 122 may be a hydrogen-rich dielectric material, such as hydrogen-rich silicon nitride. For example, the dielectric liner layer 122 may be represented as Si_{w}NₓC_{y}H_{z}, where W, X, Y, and Z are the atomic percentages of silicon, nitrogen, carbon, and hydrogen, respectively, and are less than 1. In some embodiments, W ranges from about 30% to 40%, X ranges from about 38% to 48%, Y ranges from about 1% to 10%, and Z ranges from about 5% to 20%. In some embodiments, the hydrogen concentration (i.e., Z) of the dielectric liner layer 122 may be higher than about 10%, or even higher than about 15%.

The dielectric liner layer 122 may be deposited by plasma-enhanced chemical vapor deposition (PECVD). In some embodiments, the plasma-enhanced chemical vapor deposition uses silicon-containing precursors (e.g., silane (SiH₄) and/or tetramethylsilane (TMS)) and nitrogen-containing precursors (e.g., ammonia (NH₃) and/or nitrogen (N₂)).

During the operation (e.g., read, write, and/or refresh operations) of the semiconductor memory device (e.g., DRAM), when a voltage difference exists between the gate terminal and the source terminal, a negative gate voltage may cause hydrogen dissociation at the interface between the semiconductor substrate 102 and the gate dielectric layer 110, resulting in the breakage of Si—H bonds into Si-dangling bonds. In particular, elevated temperatures resulting from the operation of the semiconductor memory device may exacerbate hydrogen dissociation. This may lead to negative bias temperature instability (NBTI) in the semiconductor memory device, resulting in increased off-state current, increased threshold voltage, and/or decreased on-state current, thereby reducing the performance and reliability of the semiconductor memory device.

In embodiments of the present invention, during the operation (e.g., during read, write, and/or refresh operation) of the semiconductor memory device, when the voltage difference between the gate terminal and the source terminal is zero, the hydrogen-rich dielectric liner layer 122 may provide sufficient hydrogen atoms diffusing to the interface between the active regions 104 (and source/drain regions 106) and the gate dielectric layer 110. As a result, Si-dangling bonds can be repaired back to Si—H bonds. Therefore, the negative bias temperature instability (NBTI) of the semiconductor memory device can be improved.

If the hydrogen concentration of the dielectric liner layer 122 is too low (e.g., less than 5%), the dielectric liner layer 122 may not provide sufficient hydrogen to repair Si-dangling bonds.

In the trench 108′, the dielectric liner layer 122 includes vertical sections along the surface of the gate dielectric layer 110 and a horizontal section along the upper surface of the second work function layer 118. The dielectric liner layer 122 formed by plasma-enhanced chemical vapor deposition may have a low conformality. For example, in the trench 108′, each section of the dielectric liner layer 122 may have a maximum thickness T1 at its middle location, and a minimum thickness T2 at its edges. Thickness T1 is greater than thickness T2. Thickness T1 may range from about 3.5 nanometers (nm) to about 14 nm, while thickness T2 may range from about 1.5 nm to about 6 nm. In some other embodiments, the dielectric liner layer 122 may have better conformality, with thickness T1 being approximately equal to thickness T2.

In some embodiments, after depositing the dielectric liner layer 122, the trench 108′ may have a sandglass shape, with a neck portion at its middle height. The sidewalls of the trench 108′ taper from both the top and bottom of the trench towards the neck portion. For example, the trench 108′ may have a minimum width D1′ at its middle height and a maximum width D2′ at its top or bottom. The width D1′ is less than the width D2′. The width D1′ may range from about 3.5 nm to about 14 nm, while the width D2′ may range from about 4.5 nm to about 18 nm. In the embodiments where the dielectric liner layer 122 has better conformality, the width D1′ may be approximately equal to the width D2′.

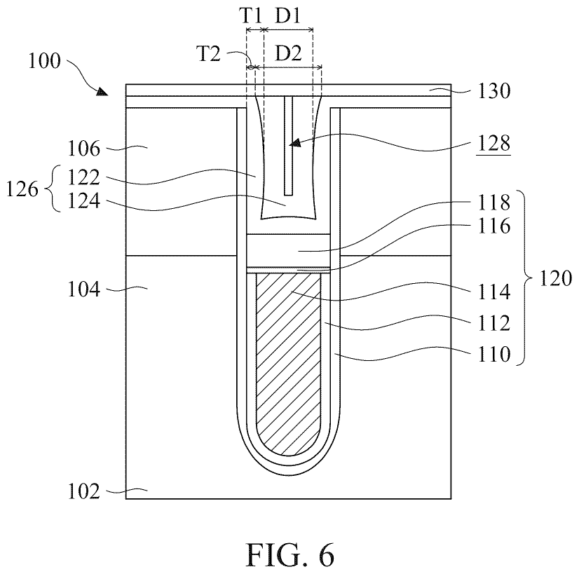

Referring to FIG. 6, a dielectric fill layer 124 is formed over the dielectric liner layer 122 to fill the remaining portion of the trench 108′. The dielectric fill layer 124 and dielectric liner layer 122 may together form an insulating structure 126. The dielectric fill layer 124 is made of dielectric materials such as silicon nitride (SiN), silicon dioxide (SiO), silicon oxynitride (SiON), silicon oxycarbide (SiOC), silicon carbon oxynitride (SiOCN), silicon carbon nitride (SiCN), and/or combinations thereof.

The dielectric fill layer 124 may be pure or substantially pure silicon nitride. For example, the dielectric fill layer 124 may be represented as Si_{w}NₓC_{y}H_{z}, where W, X, Y, and Z are the atomic percentages of silicon, nitrogen, carbon, and hydrogen, respectively, and are less than 1. In some embodiments, W ranges from about 40% to 45%, X ranges from about 55% to 60%, Y is less than 1%, and Z is less than 1%. In some embodiments, the hydrogen concentration (i.e., Z) of the dielectric fill layer 124 is lower than that the hydrogen concentration of the dielectric liner layer 122, for example, less than about 0.1%. In other embodiments, the hydrogen concentration of the dielectric fill layer 124 is substantially zero. The ratio of the hydrogen concentration of the dielectric liner layer 122 to the hydrogen concentration of the dielectric fill layer 124 can be greater than 10, for example, greater than 100, or even greater than 1000.

In the embodiments where both the dielectric liner layer 122 and the dielectric fill layer 124 contain silicon nitride, the silicon concentration (i.e., W) and nitrogen concentration (i.e., X) of the dielectric fill layer 124 may be higher than the silicon concentration and nitrogen concentration of the dielectric liner layer 122, respectively. Additionally, the carbon concentration (i.e., Y) of the dielectric fill layer 124 is lower than that of the dielectric liner layer 122. The dielectric fill layer 124, having lower impurities (such as carbon and hydrogen), can maintain the insulating structure 126 with good oxidation blocking properties, thereby protecting the underlying gate electrode.

The dielectric fill layer 124 may be deposited using atomic layer deposition (ALD) or plasma-enhanced atomic layer deposition (PEALD). Compared to plasma-enhanced chemical vapor deposition, atomic layer deposition provides better gap-filling capability. In some embodiments, atomic layer deposition uses silicon-containing precursors (e.g., dichlorosilane (DCS)) and nitrogen-containing precursors (e.g., ammonia (NH₃) and/or nitrogen (N₂)). In some embodiments, the hydrogen atomic percentage in the silicon-containing precursor used for depositing the dielectric liner layer 122 (e.g., silane (SiH₄)) is higher than the hydrogen atomic percentage in the silicon-containing precursor used for depositing the dielectric fill layer 124 (e.g., dichlorosilane (DCS)). After depositing the dielectric fill layer 124, an etching-back process is performed to expose the dielectric liner layer 122 formed above the active region 104.

In some embodiments, a seam or void 128 may exist within the dielectric fill layer 124. For example, the dielectric fill layer 124 may be deposited to incompletely fill the trench 108′, leaving the seam or void 128. Alternatively, during the etching-back process for the dielectric fill layer 124, a portion of the dielectric fill layer 124 within the trench 108′ may be etched away, thereby forming the seam or void 128. In other embodiments, there may be no seams or voids existing within the dielectric fill layer 124.

Diluted hydrofluoric acid (e.g., diluted to 100:1) has a lower etch rate for the dielectric liner layer 122 compared to its etch rate for the dielectric fill layer 124. This is advantageous for reducing the loss of the dielectric liner layer 122 during the etching-back process of the dielectric fill layer 124. Furthermore, in the embodiments where both the dielectric liner layer 122 and the dielectric fill layer 124 contain silicon nitride, the refractive index (RI) of the dielectric liner layer 122 is higher than that of the dielectric fill layer 124.

The dielectric fill layer 124 has a sandglass shape with a neck portion at its middle height. The sidewalls of the dielectric fill layer 124 taper from both the top and bottom of the dielectric fill layer 124 towards the neck portion. For example, the dielectric fill layer 124 has a minimum width D1 at its middle height (approximately equal to the width D1′) and a maximum width D2 at either its top or bottom (approximately equal to or greater than the width D2′). The width D1 is less than the width D2. In some embodiments where the dielectric liner layer 122 has better conformality, the width D1 is approximately equal to the width D2.

In some embodiments, the ratio (T1/D1) of the thickness T1 to the width D1 ranges from about 0.8 to about 1.2. In some embodiments, the ratio (T2/D2) of the thickness T2 to the width D2 ranges from about 0.25 to about 0.4. If the ratio (T1/D1 or T2/D2) is too large, it may increase the difficulty of the deposition process for the dielectric fill layer 124, leading to excessive volume of the void formed within the dielectric fill layer 124. If the ratio (T1/D1 or T2/D2) is too small, the dielectric liner layer 122 may not provide sufficient hydrogen to repair Si-dangling bonds.

A dielectric cap layer 130 is formed over the insulating structure 126. The dielectric cap layer 130 may seal the void or seam 128, thereby forming an air gap. The dielectric cap layer 130 is made of dielectric materials such as silicon nitride (SiN), silicon oxide (SiO), silicon oxynitride (SiON), silicon carbide (SiC), silicon carbon oxynitride (SiOCN), silicon carbon nitride (SiCN), and/or combinations thereof. The dielectric cap layer 130 may be formed using atomic layer deposition (ALD) or low-pressure chemical vapor deposition (LPCVD).

The composition of the dielectric cap layer 130 may be substantially the same as that of the dielectric fill layer 124, such as pure or substantially pure silicon nitride. A dielectric cap layer 130 with low impurities (e.g., carbon and hydrogen) can prevent hydrogen from diffusing from the dielectric liner layer 122 to components subsequently formed above the semiconductor structure 100.

Additional components may be formed on the semiconductor structure 100 shown in FIG. 6 to fabricate a semiconductor memory device. For example, a bit line may be formed over the active regions, capacitor structures may be formed on the bit lines, and/or other suitable components may be formed. In some embodiments, the semiconductor memory device is a dynamic random-access memory (DRAM).

As described above, the embodiments of the present disclosure may provide a semiconductor structure with an embedded gate structure and methods for forming the same. The insulating structure above the gate structure includes a hydrogen-rich dielectric liner layer. The dielectric liner layer can provide sufficient hydrogen atom diffusing to the interface between the active region and the gate dielectric layer, enabling the repair of Si-dangling bonds. Therefore, the negative bias temperature instability (NBTI) of the semiconductor memory device may be improved, thereby enhancing performance and reliability of the semiconductor memory device.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
an active region over a semiconductor substrate;
a gate structure embedded in the active region and including a gate dielectric layer and a gate electrode nested within the gate dielectric layer; and
an insulating structure embedded in the active region and over the gate electrode, wherein the insulating structure includes a dielectric liner layer and a dielectric fill layer nested within the dielectric liner layer, wherein the dielectric liner layer has a first hydrogen concentration, and the dielectric fill layer has a second hydrogen concentration that is lower than the first hydrogen concentration.

2. The semiconductor structure as claimed in claim 1, wherein a ratio of the first hydrogen concentration to the second hydrogen concentration is greater than 10.

3. The semiconductor structure as claimed in claim 1, further comprising:
a dielectric cap layer covering the insulating structure and directly contacting the dielectric liner layer and the dielectric fill layer.

4. The semiconductor structure as claimed in claim 1, wherein a first refractive index of the dielectric liner layer is greater than a second refractive index of the dielectric fill layer.

5. The semiconductor structure as claimed in claim 1, wherein the dielectric liner layer has a first carbon concentration, and the dielectric fill layer has a second carbon concentration that is less than the first carbon concentration.

6. The semiconductor structure as claimed in claim 1, wherein:
the dielectric liner layer has a first silicon concentration, and the dielectric fill layer has a second silicon concentration that is greater than the first silicon concentration; and
the dielectric liner layer has a first nitrogen concentration, and the dielectric fill layer has a second nitrogen concentration that is greater than the first nitrogen concentration.

7. The semiconductor structure as claimed in claim 1, wherein the dielectric fill layer has a neck portion at a middle height of the dielectric fill layer, and the sidewalls of the dielectric fill layer taper from both a top and a bottom of the dielectric fill layer towards the neck portion.

8. The semiconductor structure as claimed in claim 1, wherein the dielectric liner layer is in direct contact with a sidewall and a top surface of the gate dielectric layer.

9. The semiconductor structure as claimed in claim 1, wherein the gate electrode includes a first work function layer and a second work function layer over the first work 2 function layer.

10. The semiconductor structure as claimed in claim 1, wherein the semiconductor structure is a dynamic random access memory device, and during operation of the dynamic random access memory device, hydrogen atoms diffuse from the dielectric liner layer to an interface between the active region and the gate dielectric layer.

11. A method for forming a semiconductor structure, comprising:
forming a trench in an active region;
forming a gate dielectric layer along the trench;
forming a gate electrode on the gate dielectric layer to fill a lower portion of the trench;
depositing a dielectric liner layer over the gate electrode to partially fill an upper portion of the trench, wherein the dielectric liner layer contains hydrogen and has a hydrogen concentration greater than 5%; and
depositing a dielectric fill layer over the dielectric liner layer to fill the upper portion of the trench.

12. The method for forming the semiconductor structure as claimed in claim 11, wherein depositing the dielectric liner layer over the gate electrode comprises using a plasma-enhanced chemical vapor deposition, and depositing the dielectric fill layer over the dielectric liner layer comprises using an atomic layer deposition or a plasma-enhanced atomic layer deposition.

13. The method for forming the semiconductor structure as claimed in claim 11, wherein:
depositing the dielectric liner layer over the gate electrode comprises using a first silicon-containing precursor, and hydrogen in the first silicon-containing precursor has a first atomic percentage; and
depositing the dielectric fill layer over the dielectric liner layer comprises using a second silicon-containing precursor, and hydrogen in the second silicon-containing precursor has a second atomic percentage that is lower than the first atomic percentage.

14. The method for forming the semiconductor structure as claimed in claim 11, wherein the dielectric liner layer has a vertical section extending along the gate dielectric layer, the vertical section has a first thickness at a middle height of the vertical section and a second thickness at a bottom of the vertical section, and the second thickness is less than the first thickness.

15. The method for forming the semiconductor structure as claimed in claim 14, wherein the dielectric fill layer has a first width at a middle height of the dielectric fill layer and a second width at a bottom of the dielectric fill layer, and the second width is greater than the first width.

16. The method for forming the semiconductor structure as claimed in claim 15, wherein a ratio of the first thickness of the vertical section to the first width of the dielectric fill layer is in a range from about 0.8 to about 1.2.

17. The method for forming the semiconductor structure as claimed in claim 11, further comprising:
etching away a portion of the dielectric fill layer over the active region to expose a portion of the dielectric liner layer over the active region; and
forming a dielectric cap layer on the portion of the dielectric liner layer over the active region.

18. The method for forming the semiconductor structure as claimed in claim 11, wherein the dielectric liner layer includes a first silicon nitride, the dielectric fill layer includes a second silicon nitride, a first etching rate of the first silicon nitride with respect to a diluted hydrofluoric acid is lower than a second etching rate of the second silicon nitride with respect to the diluted hydrofluoric acid.

19. The method for forming the semiconductor structure as claimed in claim 11, wherein forming the gate electrode over the gate dielectric layer comprises:
forming a first gate liner layer;
forming a metal layer on the first gate liner layer;
forming a second gate liner layer on the metal layer; and
forming a semiconductor layer on the second gate liner layer.

20. The method for forming the semiconductor structure as claimed in claim 19, wherein the gate dielectric layer is in direct contact with the first gate liner layer, the second gate liner layer and the semiconductor layer.
